(19) United States
(12) Patent Application Publication
(10) Pub. No.: US 2014/0111704 A1
(43) Pub. Date: Apr. 24, 2014

(54) TELEVISION RECEIVER, ELECTRONIC APPARATUS, AND SUBSTRATE ASSEMBLY

(71) Applicant: KABUSHIKI KAISHA TOSHIBA, Tokyo (JP)

(72) Inventors: Shinya HAYASHIYAMA, Tokyo (JP); Shigeki NISHIYAMA, Tokyo (JP); Hirofumi MORITA, Tokyo (JP); Hideo SHIRASAKA, Tokyo (JP); Makoto TANAKA, Tokyo (JP); Daisuke MAEHARA, Tokyo (JP)

(21) Appl. No.: 13/924,967

(22) Filed: Jun. 24, 2013

(30) Foreign Application Priority Data
Oct. 24, 2012 (JP) 2012-235076

(51) Int. Cl. H04N 5/64; H05K 1/02

(52) U.S. Cl. CPC H04N 5/64; H05K 1/0271
USPC 348/836; 361/752; 174/250

(57) ABSTRACT

According to one embodiment, a television receiver includes: a housing; a display in the housing; a substrate configured to be accommodated in the housing and comprising a first opening; and a part configured to be mounted on a surface of the substrate and exhibit a square outer shape on a line of sight from a thickness direction of the substrate, wherein the substrate comprises a second opening in a first region that is sandwiched between extended lines of two sides sandwiching a corner of the part on the line of sight from the thickness direction of the substrate and is at a side opposite to the part with respect to the corner, at a position that is overlapped with a straight line connecting the corner of the part and center of the first opening on the line of sight from the thickness direction of the substrate.

### CROSS-REFERENCE TO RELATED APPLICATIONS

This application is based upon and claims the benefit of priority from Japanese Patent Application No. 2012-235076, filed Oct. 24, 2012, the entire contents of which are incorporated herein by reference.

### FIELD

Embodiments described herein relate generally to a television receiver, an electronic apparatus, and a substrate assembly.

### BACKGROUND

Conventionally, electronic apparatuses having a slit on a substrate accommodated in a housing have been known.

An external force acting on the substrate in the electronic apparatuses of this type, for example, may cause several problems including an increased stress on a bonding region between the substrate and a part, depending on the position, the size, and the like of the slit.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view illustrating an example of a television receiver according to a first embodiment;

FIG. 2 is an exemplary side view illustrating the example of the television receiver in the first embodiment;

FIG. 3 is an exemplary plan view (rear view) illustrating a part of a substrate assembly accommodated in a housing of the example of the television receiver in the first embodiment;

FIG. 4 is an exemplary plan view (rear view) illustrating a part of the substrate assembly accommodated in the housing of the example of the television receiver in the first embodiment and is an exemplary diagram for explaining a positional relationship of parts;

FIG. 5 is an exemplary perspective view illustrating an example of an electronic apparatus according to a second embodiment;

FIG. 6 is an exemplary plan view illustrating a schematic configuration of a substrate assembly accommodated in a housing of the example of the electronic apparatus in the second embodiment;

FIG. 7 is an exemplary plan view illustrating a part of the substrate assembly accommodated in the housing of the example of the electronic apparatus in the second embodiment and is an exemplary diagram for explaining a positional relationship of parts;

FIG. 8 is an exemplary plan view illustrating a part of a substrate assembly accommodated in a housing of an example of an electronic apparatus according to a first modification and is an exemplary diagram for explaining a positional relationship of parts;

FIG. 9 is an exemplary plan view illustrating a part of a substrate assembly accommodated in a housing of an example of an electronic apparatus according to a second modification and is an exemplary diagram for explaining a positional relationship of parts;

FIG. 10 is an exemplary plan view illustrating a part of a substrate assembly accommodated in a housing of an example of an electronic apparatus according to a third modification and is an exemplary diagram for explaining a positional relationship of parts;

FIG. 11 is an exemplary plan view illustrating a part of a substrate assembly accommodated in a housing of an example of an electronic apparatus according to a fourth modification and is an exemplary diagram for explaining a positional relationship of parts;

FIG. 12 is an exemplary plan view illustrating a part of a substrate assembly accommodated in a housing of an example of an electronic apparatus according to a fifth modification and is an exemplary diagram for explaining a positional relationship of parts;

FIG. 13 is an exemplary plan view illustrating a part of a substrate assembly accommodated in a housing of an example of an electronic apparatus according to a sixth modification and is an exemplary diagram for explaining a positional relationship of parts;

FIG. 14 is an exemplary plan view illustrating a part of a substrate assembly accommodated in a housing of an example of an electronic apparatus according to a seventh modification and is an exemplary diagram for explaining a positional relationship of parts; and

FIG. 15 is an exemplary plan view illustrating a part of a substrate assembly accommodated in a housing of an example of an electronic apparatus according to an eighth modification and is an exemplary diagram for explaining a positional relationship of parts

### DETAILED DESCRIPTION

In general, according to one embodiment, a television receiver comprises: a housing; a display device in the housing; a substrate in the housing and comprising a first opening; and a part on a surface of the substrate and comprising a square outer shape when viewed from a direction normal to the substrate, wherein the substrate comprises a second opening in a first region, the first region formed by a first line extending from a first side of the part and a second line extending from a second side of the part, the first line crossing the second line at a corner of the part, and at a side opposite to the part when viewed from the direction normal to the substrate, wherein the second opening is on a line connecting the corner and a center of the first opening.

In the following, a plurality of embodiments and modifications comprise the same or similar constituent components. Therefore, hereinafter, common reference numerals denote the same or similar constituent components and overlapped explanation thereof is omitted. In addition, parts comprised in each embodiment and modification can be replaced with corresponding parts in other embodiments and modifications.

Furthermore, in the following embodiments, an electronic apparatus is configured as a television receiver or a clamshell-type (notebook-type, folding-type) personal computer. However, an electronic apparatus according to the embodiments is not limited thereto. The electronic apparatus according to the embodiments can be configured as various types of electronic apparatuses in which a substrate (substrate assembly) is accommodated in a housing. Examples of the electronic apparatus according to the embodiments may include tablet-type personal computers, smart phones, electronic book terminals, smart books, mobile phones, personal digital assistants (PDAs), video image display devices, video phones, video display control devices, and information storage devices.

### First Embodiment

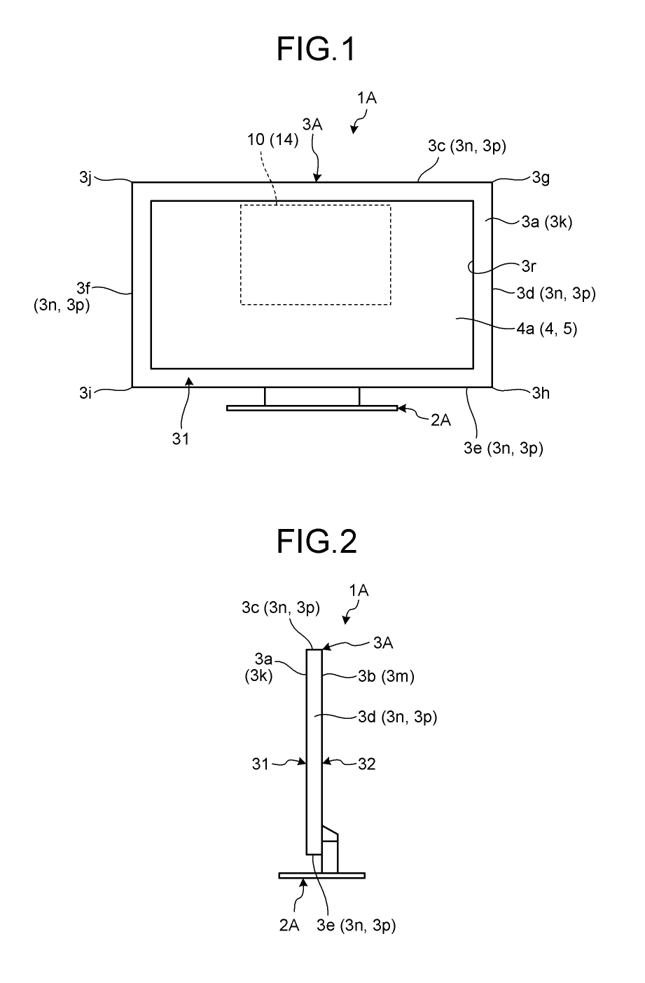

In this embodiment, as illustrated in FIGS. 1 and 2, a television receiver 1A as an example of an electronic apparatus comprises a supporting portion 2A (support, base, stand) and a housing 3A, as an example. To be more specific, the supporting portion 2A is placed on a placement portion (placement surface, not illustrated) such as a desk, a shelf, or a board and supports the housing 3A in an erected state. The supporting portion 2A may support the housing 3A in a fixed manner or in a movable manner (rotatable manner, slidable manner). Movement patterns of the housing 3A with respect to the supporting portion 2A include tilt, swivel, and pivot.

In the embodiment, as illustrated in FIG. 1, the housing 3A has a square outer shape (in the embodiment, landscape rectangular shape as an example) when viewed from the front side and the rear side, as an example. As illustrated in FIG. 2, the housing 3A is configured to have a flattened rectangular parallelepiped shape that is thin in the front-rear direction (thickness direction of the housing 3A, right-left direction in FIG. 2). The housing 3A comprises a surface 3a (front surface, front, surface portion), a surface 3b (rear surface, back surface, surface portion) at the side opposite to the surface 3a, and surfaces 3p (side surfaces, surface portions) connecting the surface 3a and the surface 3b. Both the surface 3a and the surface 3b intersect with the thickness direction. The surface 3a and the surface 3b are substantially parallel to each other. The surfaces 3a and 3b and the surfaces 3p intersect with one another (in the embodiment, are orthogonal to one another, as an example). The housing 3A comprises four ends 3c to 3f (sides, edges, peripheral edges) and four corners 3g to 3j (sharp portions, bent portions, ends) when viewed from the front side. The ends 3c and 3e are examples of long sides, whereas the ends 3d and 3f are examples of short sides.

The housing 3A comprises a wall portion 3k (portion, plate, front wall portion, surface wall portion, ceiling wall portion, first wall portion), a wall portion 3m (portion, plate, back wall portion, rear wall portion, bottom wall portion, second wall portion), and wall portions 3n (portions, plates, side wall portions, end wall portions, erected wall portions, connecting portions, third wall portions). The wall portion 3k has the surface 3a. The wall portion 3m has the surface 3b. The wall portions 3n have the surfaces 3p. The wall portions 3k, 3m, and 3n all have square shapes (in the embodiment, rectangular shapes as an example). Furthermore, the wall portions 3k, 3m, and 3n are all plate-like portions. The wall portion 3k has a square-shaped opening 3r.

The housing 3A is configured by combining a plurality of parts (divided members, members). The housing 3A comprises a member 31 (front-side member, cover, bezel, plate, first member) and a member 32 (back-side member, base, bottom, plate, second member), as an example. The member 31 comprises the wall portion 3k. The member 32 comprises the wall portion 3m. The wall portions 3n are comprised in at least one of the member 31 and the member 32 (in the embodiment, member 32 as an example). The members 31 and 32 can be formed with a metal material, a synthetic resin material, or the like. The metal material can be machined by sintering, press, cutting, or the like. The synthetic resin material can be machined by injection molding or the like. It is to be noted that the housing 3A can have different members (not illustrated) from the members 31 and 32.

Furthermore, in the embodiment, the housing 3A accommodates a display device 4 (display module, display, panel, display part), as an example. To be more specific, a user can visually recognize a display screen 4a of the display device 4 through the opening 3r from the front side. The display device 4 has a square outer shape (in the embodiment, rectangular shape as an example) when viewed from the front side. Furthermore, the display device 4 is configured to have a flattened rectangular parallelepiped shape that is thin in the front-rear direction. For example, the display device 4 is a liquid crystal display (LCD) or an organic electro-luminescent (EL) display (GELD).

Furthermore, in the embodiment, at the front side (surface side, wall portion 3k side) of the display device 4, provided is a transparent and relatively thin square-shaped input operation panel 5 (as an example, touch panel, touch sensor, operation surface, input operation module, input receiving module), as an example. The input operation panel 5 covers the display screen 4a. An operator (user or the like) performs an operation on the input operation panel 5 with his (her) fingers, a stylus, or the like so as to execute input processing. The operation by the user includes touching, pressing, sliding, or moving his (her) fingers, the stylus, or the like in the vicinity of the input operation panel 5. Light emitted from the display screen 4a of the display device 4 passes through the input operation panel 5 so as to travel from the opening 3r of the wall portion 3k to the front side (outer side) of the housing 3A. The input operation panel 5 is an example of an input module. In the embodiment, the display device 4 and the input operation panel 5 are fixed to (supported on) the housing 3A through a fixing tool (fixing part, clasp; for example, screw, clasp, or part, not illustrated) or an adhesion portion (for example, adhesive, double-stick tape, not illustrated), as an example. It is to be noted that the input operation panel 5 may be configured as an in-cell touch panel comprised in the display device 4.

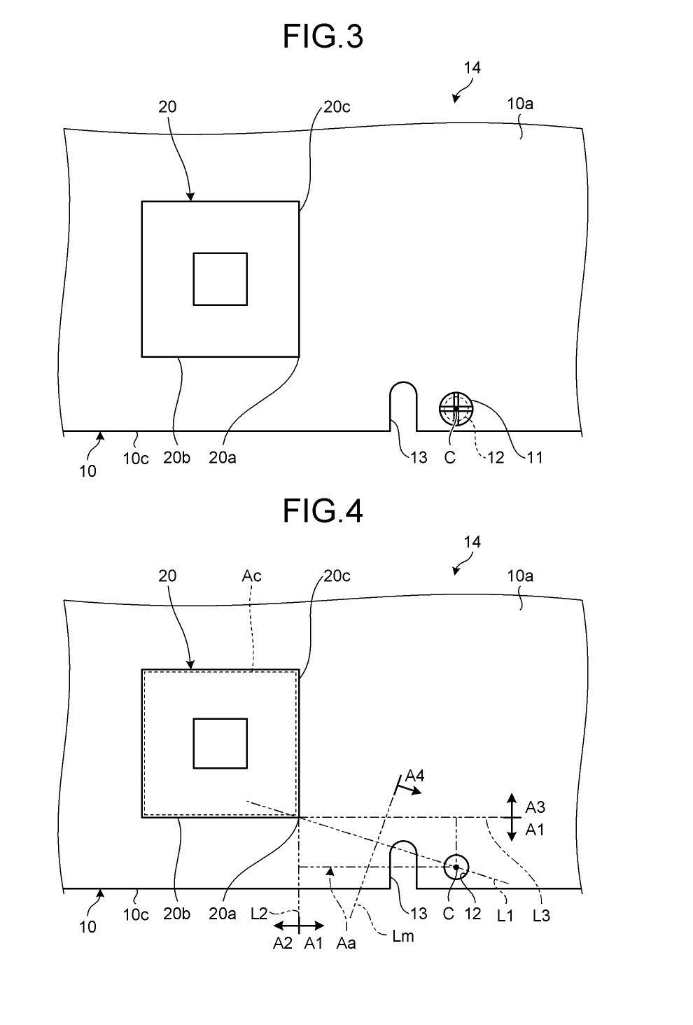

Furthermore, in the embodiment, as illustrated in FIG. 1, the housing 3A accommodates a substrate 10 (printed wiring board, circuit board, control board, part), as an example. The substrate 10 is coupled (connected, fixed) to the housing 3A with a coupling tool 11 (in this embodiment, screw as an example; see FIG. 3). To be more specific, the substrate 10 comprises an opening 12 (first opening, for example, through-hole or cutout; see FIGS. 3 and 4). The coupling tool 11 is fixed to the housing 3A through the opening 12. The substrate 10 is sandwiched between the coupling tool 11 fixed to the housing 3A and the housing 3A. In the embodiment, the opening 12 is a through-hole provided on (in the vicinity of) an end 10c of the substrate 10, as an example. A plurality of parts (electronic parts, electric parts, elements; as an example, part 20 (see, FIGS. 3 and 4)) are mounted on the substrate 10 so as to constitute a substrate assembly 14. It is to be noted that FIGS. 3 and 4 illustrate, for convenience, only the part 20 having a relatively large size but not smaller parts.

The part 20 (electronic part, electric part, package, element), illustrated in FIGS. 3 and 4, is a surface mounted part. The part 20 is electrically and mechanically connected (bonded) to an electrode (not illustrated) exposed to a surface 10a of the substrate 10 by soldering or the like. The part 20 has a square outer shape (polygonal shape; in this embodiment, regular tetragon as an example) when viewed from the above. To be more specific, on a surface (not illustrated) of the part 20 that is opposed to the surface 10a of the substrate 10, provided is an electrode (pad or the like, not illustrated), for example. The electrode is electrically and mechanically connected to the electrode provided on the surface 10a with a bonding member (solder or the like). The part 20 is, for example, a ball grid array (BGA), a land grid array (LGA), or a quad flat no lead package (QFN).

The substrate 10 is adapted to receive an external force from the housing 3A through a coupling portion (contact portion, connecting portion, or fixing portion; a portion on which the coupling tool 11 is provided, as an example (see, FIG. 3)) between the substrate 10 and the housing 3A. If the external force increases stress in a bonding region Ac (in FIG. 4, illustrated in a square shape in a simplified manner for convenience) between the substrate 10 and the part 20, this could cause disadvantageous matters such as generation of a crack on the bonding member (for example, solder) and stripping of the part 20 from the substrate 10. In order to avoid this, in the embodiment, the substrate 10 has an opening 13 to prevent an increase in the stress in the bonding region Ac when the external force acts. That is to say, the opening 13 reduces the stress in the bonding region Ac. The opening 13 is a cutout or a through-hole, for example. In the embodiment, the opening 13 is a cutout provided on the end 10c (in the vicinity of the end, edge portion, in the vicinity of the edge portion) of the substrate 10, as an example.

Rigorous studies about the opening 13 made by the inventors have revealed some aspects about a stress decreasing effect in accordance with specifications of the opening 13.

First, as illustrated in FIG. 4, it has been found that stress in the bonding region Ac decreases when the opening 13 is provided at a position on a straight line L1 connecting a corner 20a of the part 20 and the center C (center of the coupling tool 11) of the opening 12, viewed from the thickness direction of the substrate 10 (planar view of the surface 10a of the substrate 10, viewed from the orthogonal direction or the normal line direction of the surface 10a), as an example. That is to say, the opening 13, when provided at the above-mentioned position, lowers rigidity of the substrate 10 in a region between the opening 12 (coupling tool 11) and the bonding region Ac. This suppresses increases in stress in the bonding region Ac due to the external force input from the coupling tool 11 and in energy to be transmitted as a stress wave.

In addition, as illustrated in FIG. 4, it has been found that the opening 13, when provided in a region A1 (first region) viewed from the thickness direction of the substrate 10, as an example, decreases stress in the bonding region Ac. The region A1 is a region that is sandwiched between extended lines L2 and L3 of two sides 20b and 20c sandwiching the corner 20a of the part 20 and is located at the side opposite to the part 20 with respect to the corner 20a. If the opening 12 is provided in a region A2 or A3 that is located at a side position of the part 20 viewed from the thickness direction of the substrate 10 and is opposed to the side 20b or 20c of the part 20 and the substrate is adapted to receive an external force from a coupling tool (not illustrated) accommodated in the opening 12, then a relatively large region along the side 20b or 20c of the bonding region Ac is opposed to the opening 12 (coupling tool) to reduce an increase in local stress in the region along the side 20b or 20c of the bonding region Ac. If the opening 12 is provided in the region A1 located at a side position of the part 20 viewed from the thickness direction of the substrate 10 and is opposed to the corner 20a of the part 20 and the substrate 10 is adapted to receive an external force from the coupling tool 11 accommodated in the opening 12, stress tends to increase locally in a relatively narrow region (region in the vicinity of the corner 20a) corresponding to the corner 20a of the bonding region Ac. The regions A2 and A3 are regions on which a plurality of (a number of) wires are arranged and thus are not suitable for the opening 13 to be provided. Accordingly, the opening 13, when provided in the region A1, more effectively reduces an increase in the local stress in the region corresponding to the corner 20a of the bonding region AC.

In addition, as illustrated in FIG. 4, it has been found that the opening 13 located in a region Aa (second region) having a rectangular shape viewed from the thickness direction of the substrate 10, as an example, decreases the stress on the bonding region Ac. In this case, the corner 20a of the part 20 and the center C of the opening 12 correspond to two diagonal corners of the region Aa having the rectangular shape. The extended lines L2 and L3 of the two sides 20b and 20c sandwiching the corner 20a of the part 20 correspond to two adjacent sides of the region Aa having the rectangular shape. The opening 13, when provided on a portion at the outer side of the region Aa in the region A1, less contributes to a decrease in the stress.

Furthermore, as illustrated in FIG. 4, it has been found that the opening 13 located closer to the opening 12 rather than to the corner 20a of the part 20 viewed from the thickness direction of the substrate 10 (in a region A4 on the opening 12 side of a perpendicular bisector Lm of a line segment passing through the corner 20a and the center C), as an example, decreases the stress in the bonding region Ac. When the opening 13 is closer to the opening 12 rather than to the corner 20a of the part 20, energy (load) due to the external force input to the substrate 10 from the coupling tool 11 tends to be prevented from being transmitted to a wider range in the substrate 10.

Furthermore, in the embodiment, the housing 3A accommodates a plurality of parts (electronic parts, electric parts, packages, elements; as an example, part 20), as an example. The part 20 and the like mounted on the substrate 10 constitute at least a part of a control circuit (not illustrated). The control circuit can comprise a video image signal processing circuit, a tuner module, a high-definition multimedia interface (HDMI) signal processor, an audio video (AV) input terminal, a remote control signal receiver, a controller, a selector, an on-screen display interface, a storage module (for example, a read only memory (ROM), a random access memory (RAM), a hard disk drive (HDD)), and an audio signal processing circuit, for example. The control circuit controls output of a video image (moving image, still image, or the like) on the display screen 4a of the display device 4, audio output with a speaker (not illustrated), light emission from a light emitting diode (LED) (not illustrated), and the like. The display device 4, the speaker, the LED, and the like are examples of an output module.

As described above, in the embodiment, the substrate 10 has the opening 13 (second opening) at a position on the straight line L1 in the region A1 viewed from the thickness direction of the substrate 10, as an example. As a result, according to the embodiment, rigidity of the substrate 10 is lowered in a region between the opening 12 (coupling tool 11) and the bonding region Ac between the substrate 10 and the part 20. This tends to suppress increases in stress in the bonding region Ac due to the external force input from the coupling tool 11 and in energy to be transmitted as a stress wave.

Furthermore, in the embodiment, at least a part of the opening 13 is located in the region Aa having the rectangular shape viewed from the thickness direction of the substrate 10, as an example. As a result, according to the embodiment, an increase in the stress is more effectively suppressed in the region corresponding to the corner 20a of the bonding region AC, as an example.

In addition, in the embodiment, the opening 13 is located at a position closer to the opening 12 (in the region A4) rather than to the corner 20a of the part 20, viewed from the thickness direction of the substrate 10, as an example. As a result, according to the embodiment, energy (load) due to the external force input to the substrate 10 from the coupling tool 11 tends to be prevented from being transmitted to a wider range in the substrate 10.

Furthermore, in the embodiment, the opening 13 is a cutout provided on the end 10c of the substrate 10, as an example. Thus, according to the embodiment, the opening 13 is provided more easily, as an example. In addition, when the opening 13 is provided on the end 10c, an influence on mounting of other parts, wires, and the like is smaller. In other words, limitation on the layout of the opening 13 is smaller.

Moreover, in the embodiment, the opening 13 is provided on the end 10c along the lengthwise direction of the substrate 10, as an example. When the substrate 10 is long in one direction and short in the other direction orthogonal to the one (for example, has a rectangular shape), an external force is easily generated to cause bending and deflection in the lengthwise direction. According to the embodiment, the opening 13 is provided on the end 10c along the lengthwise direction of the substrate 10, as an example. If the external force that causes bending and deflection in the lengthwise direction acts on the substrate 10, an increase in stress in the bonding region Ac due to the external force tends to be suppressed.

### Second Embodiment

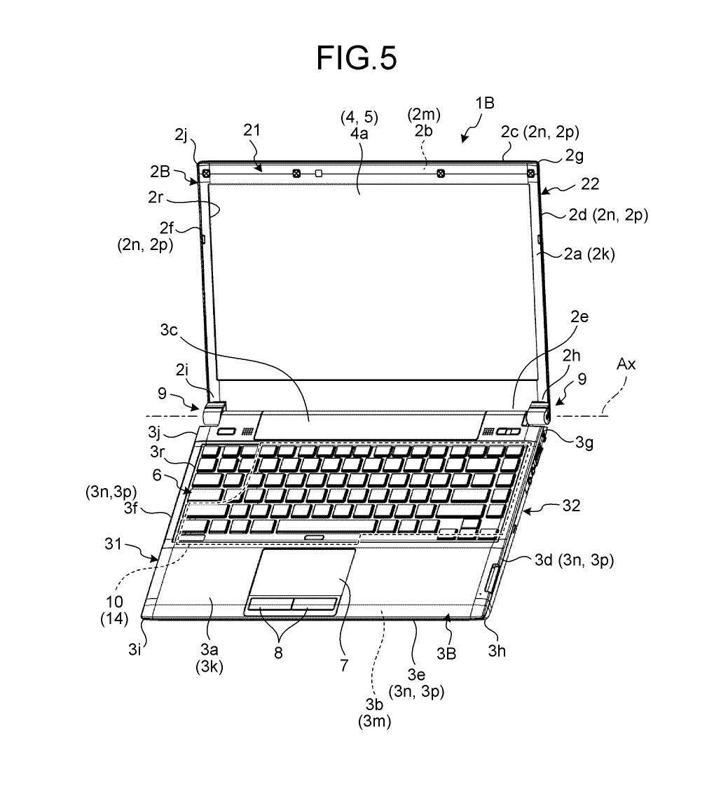

An electronic apparatus 1B according to this embodiment is what is called a notebook-type personal computer, for example. In the embodiment, as illustrated in FIG. 5, the electronic apparatus 1B comprises a housing 3B (first housing, housing, first portion) and a housing 2B (second housing, another housing, second portion), as an example. The housing 3B accommodates the substrate 10. The housing 2B accommodates at least a part of the display device 4. The housing 3B comprises a keyboard 6 (input operation module, input receiving module, input module), a touch pad 7 (input operation module, input receiving module, input module), and a click button 8 (input operation module, input receiving module, input module).

The housing 3B and the housing 2B are rotatably connected to each other with hinge portions 9 (connecting portions, coupling portions, rotational movement supporting portions, hinge mechanisms, connecting mechanisms, coupling mechanisms, rotational movement supporting mechanisms). The housing 3B and the housing 2B are rotatably connected to each other with the hinge portions 9 at least in a state between an open state as illustrated in FIG. 5 and a folded state (not illustrated). In the embodiment, the hinge portions 9 rotatably connect the housing 3B and the housing 2B about a rotational axis Ax, as an example. The display screen 4a of the display device 4 can be recognized visually through an opening 2r provided on a surface 2a (front surface, surface, surface portion) of the housing 2B. The keyboard 6, the touch pad 7, the click button 8, and the like are exposed on the surface 3a (upper surface, front surface, first surface, first surface portion) of the housing 3B. In the folded state, the surface 3a of the housing 3B and the surface 2a of the housing 2B overlap each other, so that the display screen 4a, the keyboard 6, the touch pad 7, the click button 8, and the like are hidden by the housing 3B and the housing 2B. In the open state, the surface 3a of the housing 3B and the surface 2a of the housing 2B are exposed, so that the display screen 4a, the keyboard 6, the touch pad 7, the click button 8, and the like can be used (can be recognized visually or can be operated).

In the embodiment, as illustrated in FIG. 5, the housing 2B has a square outer shape (in the embodiment, landscape rectangular outer shape as an example) when viewed from the front side and the rear side, as an example. Furthermore, in the embodiment, the housing 2B is configured to have a flattened rectangular parallelepiped shape that is thin in the front-rear direction (thickness direction of the housing 2B), as an example. The housing 2B comprises the surface 2a (front surface, front, surface portion), a surface 2b (rear surface, back surface, surface portion) at the side opposite to the surface 2a, and surfaces 2p (side surfaces, surface portions) connecting the surface 2a and the surface 2b. Both the surface 2a and the surface 2b intersect with the thickness direction. The surface 2a and the surface 2b are substantially parallel to each other. Furthermore, the surfaces 2a and 2b and the surfaces 2p intersect with one another (in the embodiment, are orthogonal to one another, as an example). In addition, the housing 2B comprises four ends 2c to 2f (sides, edges, peripheral edges) and four corners 2g to 2j (sharp portions, bent portions, ends) when viewed from the front side. The ends 2c and 2e are examples of long sides, whereas the ends 2d and 2f are examples of short sides.

The housing 2B comprises a wall portion 2k (portion, plate, front wall portion, surface wall portion, ceiling wall portion, first wall portion), a wall portion 2m (portion, plate, back wall portion, rear wall portion, bottom wall portion, second wall portion) and wall portions 2n (portions, plates, side wall portions, end wall portions, erected wall portions, connecting portions, third wall portions). The wall portion 2k has the surface 2a. The wall portion 2m has the surface 2b. The wall portions 2n have the surfaces 2p. The wall portions 2k, 2m, and 2n all have square shapes (in the embodiment, rectangular shapes as an example). Furthermore, the wall portions 2k, 2m, and 2n are all plate-like portions. The wall portion 2k has the square-shaped opening 2r.

The housing 2B is configured by combining a plurality of parts (divided members, members). The housing 2B comprises a member 21 (front-side member, cover, bezel, plate, first member) and a member 22 (back-side member, base, bottom, plate, second member), as an example. The member 21 comprises the wall portion 2k. The member 22 comprises the wall portion 2m. The wall portions 2n are comprised in at least one of the member 21 and the member 22 (in the embodiment, member 22 as an example). The members 21 and 22 can be formed with a metal material, a synthetic resin material, or the like. The metal material can be machined by sintering, press, cutting, or the like. The synthetic resin material can be machined by injection molding or the like. It is to be noted that the housing 2B can have different members (not illustrated) from the members 21 and 22.

Furthermore, in the embodiment, the housing 2B accommodates the display device 4 (display module, display, panel, display part), as an example. To be more specific, a user can recognize the display screen 4a of the display device 4 visually through the opening 2r from the front side. The display device 4 has a square outer shape (in the embodiment, rectangular shape as an example) when viewed from the front side. Furthermore, the display device 4 is configured to have a flattened rectangular parallelepiped shape that is thin in the front-rear direction. For example, the display device 4 is a liquid crystal display (LCD) or an organic electro-luminescent (EL) display (GELD).

Furthermore, in the embodiment, at the front side (surface side, wall portion 3k side) of the display device 4, provided is a transparent and relatively thin square-shaped input operation panel 5 (touch panel, touch sensor, operation surface, input operation module, input receiving module), as an example. The input operation panel 5 covers the display screen 4a. An operator (user or the like) performs an operation on the input operation panel 5 with his (her) fingers, a stylus, or the like so as to execute input processing. The operation to be performed by the user includes touching, pressing, sliding, or moving his (her) fingers, the stylus, or the like in the vicinity of the input operation panel 5. Light emitted from the display screen 4a of the display device 4 passes through the input operation panel 5 so as to travel from the opening 2r of the wall portion 2k to the front side (outer side) of the housing 2B. The input operation panel 5 is an example of an input module. Furthermore, in the embodiment, the display device 4 and the input operation panel 5 are fixed to (supported on) the housing 2B through a fixing tool (fixing part; for example, screw, clasp, or part, not illustrated) or an adhesion portion (for example, adhesive, double-stick tape, not illustrated), as an example. It is to be noted that the input operation panel 5 may be configured as an in-cell touch panel comprised in the display device 4.

In the embodiment, as illustrated in FIG. 5, the housing 3B has a square outer shape (in the embodiment, landscape rectangular shape as an example) when viewed from the front side and the rear side, as an example. Furthermore, as illustrated in FIG. 5, the housing 3B is configured to have a flattened rectangular parallelepiped shape that is thin in the front-rear direction (thickness direction of the housing 3B, left-right direction in FIG. 5). The housing 3B comprises the surface 3a (front surface, front, surface portion), the surface 3b (rear surface, back surface, surface portion) at the side opposite to the surface 3a, and the surfaces 3p (side surfaces, surface portions) connecting the surface 3a and the surface 3b. Both the surface 3a and the surface 3b intersect with the thickness direction. The surface 3a and the surface 3b are substantially parallel to each other. Furthermore, the surfaces 3a and 3b and the surfaces 3p intersect with one another (in the embodiment, are orthogonal to one another, as an example). In addition, the housing 3B comprises four ends 3c to 3f (sides, edges, peripheral edges) and four corners 3g to 3j (sharp portions, bent portions, ends) when viewed from the front side. The ends 3c and 3e are examples of long sides, whereas the ends 3d and 3f are examples of short sides.

The housing 3B comprises the wall portion 3k (portion, plate, front wall portion, surface wall portion, ceiling wall portion, first wall portion), the wall portion 3m (portion, plate, back wall portion, rear wall portion, bottom wall portion, second wall portion), and the wall portions 3n (portions, plates, side wall portions, end wall portions, erected wall portions, connecting portions, third wall portions). The wall portion 3k has the surface 3a. The wall portion 3m has the surface 3b. The wall portions 3n have the surfaces 3p. The wall portions 3k, 3m, and 3n all have square shapes (in the embodiment, rectangular shapes as an example). Furthermore, the wall portions 3k, 3m, and 3n are all plate-like portions. The wall portion 3k has the square-shaped opening 3r.

The housing 3B is configured by combining a plurality of parts (divided members, members). The housing 3B comprises the member 31 (front-side member, cover, bezel, plate, first member) and the member 32 (back-side member, base, bottom, plate, second member), as an example. The member 31 comprises the wall portion 3k. The member 32 comprises the wall portion 3m. The wall portions 3n are comprised in at least one of the member 31 and the member 32 (in the embodiment, member 32 as an example). The members 31 and 32 can be formed with a metal material, a synthetic resin material, or the like. The metal material can be machined by sintering, press, cutting, or the like. The synthetic resin material can be machined by injection molding or the like. It is to be noted that the housing 3B can have different members (not illustrated) from the members 31 and 32.

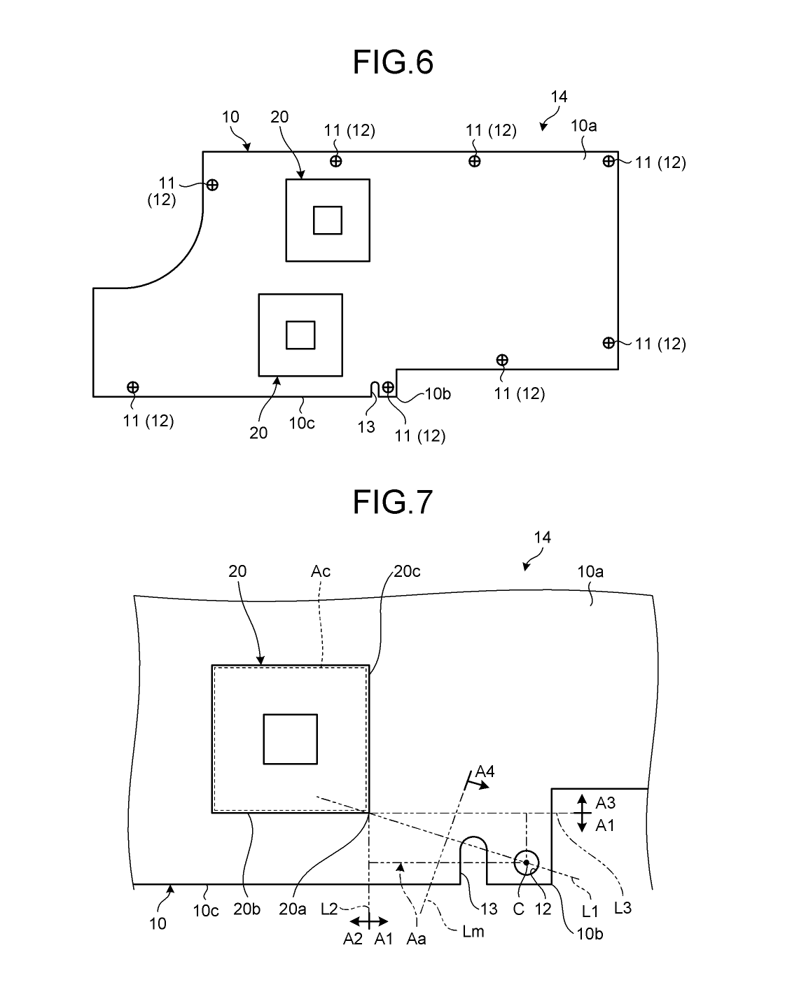

Furthermore, in the embodiment, the housing 3B accommodates equal to or more than one substrates 10 (substrate assembly 14, see FIG. 6), as an example. The substrate 10 is provided collaterally with (in the embodiment, to be parallel to, as an example) the keyboard 6 (see, FIG. 5). The substrate 10 is coupled (connected, fixed) to the housing 3B by coupling tools 11 (in the embodiment, screws as an example, see FIG. 6). The substrate 10 has openings 12 (first openings; for example, through-holes or cutouts, see FIG. 7). The coupling tools 11 are fixed to the housing 3B through the openings 12. The substrate 10 is sandwiched between the coupling tools 11 fixed to the housing 3B and the housing 3B. In the embodiment, the opening 12 is a through-hole provided on a corner 10b (in the vicinity of the corner 10b, the end 10c) of the substrate 10, as an example. A plurality of parts (electronic parts, electric parts, elements; as an example, parts 20 (see, FIGS. 6 and 7)) are mounted on the substrate 10 so as to constitute the substrate assembly 14. It is to be noted that FIGS. 6 and 7 illustrate, for convenience, only the parts 20 having relatively large sizes but not smaller parts. Also in the embodiment, as illustrated in FIG. 7, the substrate 10 (substrate assembly 14) has the same configuration as that in the first embodiment, as an example.

Furthermore, in the embodiment, the substrate 10 can mount a plurality of parts 20 such as a central processing unit (CPU), a graphics controller, a power supply circuit part, a platform controller hub, (PCH), a memory slot connecter, an LCD connector, an input/output (I/O) connector, a power supply coil, an element, and a connector, as an example. In addition, the control circuit can comprise a video image signal processing circuit, a tuner module, a high-definition multimedia interface (HDMI) signal processor, an audio video (AV) input terminal, a remote control signal receiver, a controller, a selector, an on-screen display interface, a storage module (for example, a read only memory (ROM), a random access memory (RAM), a hard disk drive (HDD), a solid state drive (SSD)), and an audio signal processing circuit, for example. The control circuit controls output of a video image (moving image, still image, or the like) on the display screen 4a of the display device 4, audio output with a speaker (not illustrated), light emission from a light emitting diode (LED) (not illustrated), and the like. The display device 4, the speaker, the LED, and the like are examples of an output module.

As illustrated in FIGS. 6 and 7, the electronic apparatus 1B according to the above-mentioned embodiment comprises configurations relating to the substrate 10 (substrate assembly 14) and the parts 20 that are the same as those of the television receiver 1A according to the first embodiment. Therefore, the same or similar results (effects) as those obtained in the first embodiment can be obtained.

First Modification

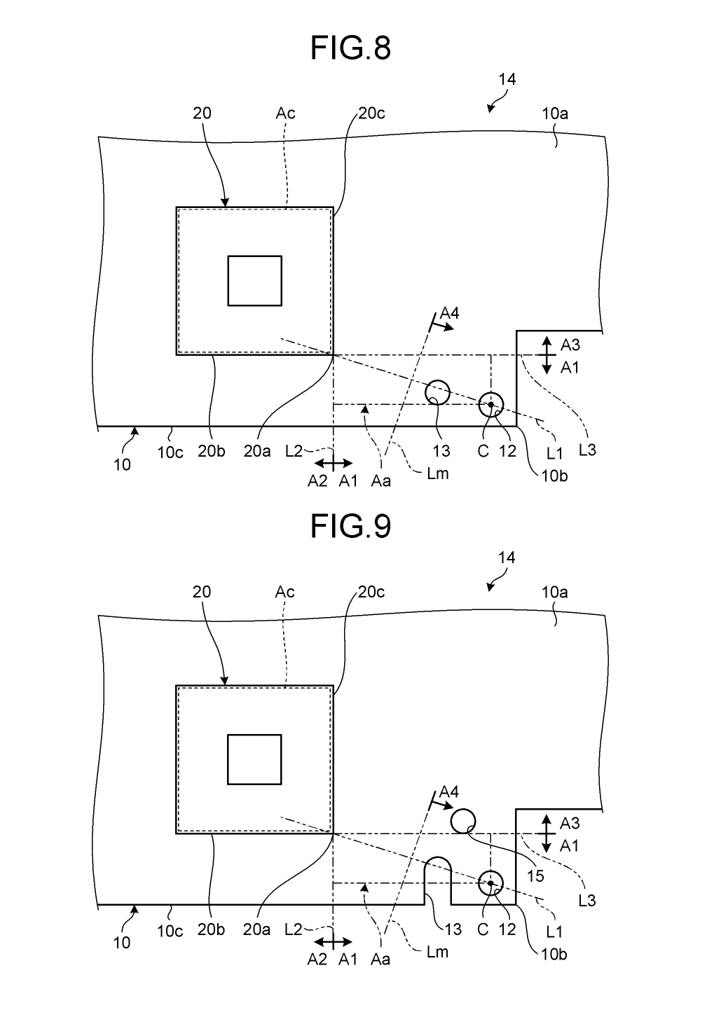

In this modification, as illustrated in FIG. 8, the opening 13 is a thorough-hole provided on the substrate 10, as an example. In the embodiment, the opening 13 is a circular through-hole when viewed from the above, as an example. However, in the modification, the opening 13 is provided at a position on the straight line L1 in the regions A1 and Aa as in the above-described embodiments. Accordingly, in the modification, the same or similar results (effects) as those obtained in the above-mentioned embodiments can be obtained.

Second Modification

In this modification, as illustrated in FIG. 9, the opening 13 that is the same as that in the above-mentioned embodiments is provided, as an example. Therefore, also in the modification, the same or similar results (effects) as those obtained in the above-mentioned embodiments can be obtained. However, in the modification, as illustrated in FIG. 9, the substrate 10 has an opening 15 (third opening) in addition to the openings 12 and 13, as an example. The opening 15 is a through-hole provided on the substrate 10. In the modification, the opening 15 is a circular through-hole when viewed from the above, as an example. The opening 15 is provided in a state where at least a part of it is overlapped with or makes contact with the regions A1 and Aa (in the modification, makes contact therewith, as an example). In addition, the opening 15 is located in the region A4. That is to say, the opening 15 is located at a position closer to the center C of the opening 12 rather than to the corner 20a. Studies by the inventors have revealed that the opening 15, when provided in addition to the opening 13, tends to reduce stress on the bonding region Ac in comparison with a case without the opening 15. That is to say, the modification tends to further suppress increases in stress on the bonding region Ac due to the external force input from the coupling tool 11 and in energy to be transmitted as a stress wave, as an example.

Third Modification

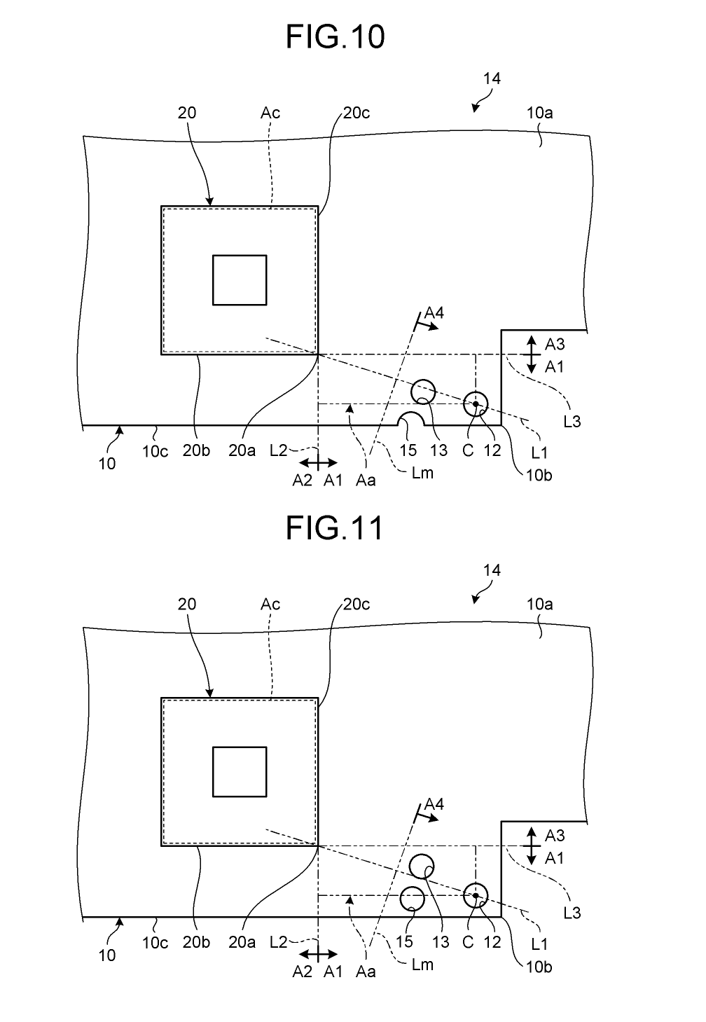

In this modification, as illustrated in FIG. 10, the substrate has the opening 13 that is the same as that in first modification, as an example. In the modification, the substrate 10 has the opening 15 (third opening) in addition to the openings 12 and 13. The opening 15 is a cutout provided on the end 10c of the substrate 10. In addition, the opening 15 is located in the region A4. That is to say, the opening 15 is located at a position closer to the center C of the opening 12 rather than to the corner 20a. Studies by the inventors have revealed that the opening 15, when provided in addition to the opening 13, tends to reduce stress on the bonding region Ac in comparison with a case without the opening 15. That is to say, the modification tends to further suppress increases in stress in the bonding region Ac due to the external force input from the coupling tool 11 and in energy to be transmitted as a stress wave, as an example.

Fourth Modification

In this modification, as illustrated in FIG. 11, the substrate 10 has the opening 13 as an example. The opening 13 is a through-hole provided on the substrate 10. In the modification, the opening 13 is a circular through-hole when viewed from the above, as an example. The opening 13 is provided in which at least a part of it is overlapped with or makes contact with the straight line L1. The substrate 10 has, in addition to the openings 12 and 13, the opening 15 (third opening) that is not overlapped with the straight line L1. In the modification, the opening 15 is a circular through-hole when viewed from the above, as an example. The opening 15 is provided in which at least a part of it is overlapped with or makes contact with the region Aa (in the modification, is overlapped therewith, as an example). Furthermore, the opening 15 is located in the region A4. That is to say, the opening 15 is located at a position closer to the center C of the opening 12 rather than to the corner 20a. Studies by the inventors have revealed that the opening 15, when provided, tends to reduce stress on the bonding region Ac in comparison with a case without the opening 15. That is to say, the modification tends to further suppress increases in stress in the bonding region Ac due to the external force input from the coupling tool 11 and in energy to be transmitted as a stress wave, as an example.

Fifth Modification

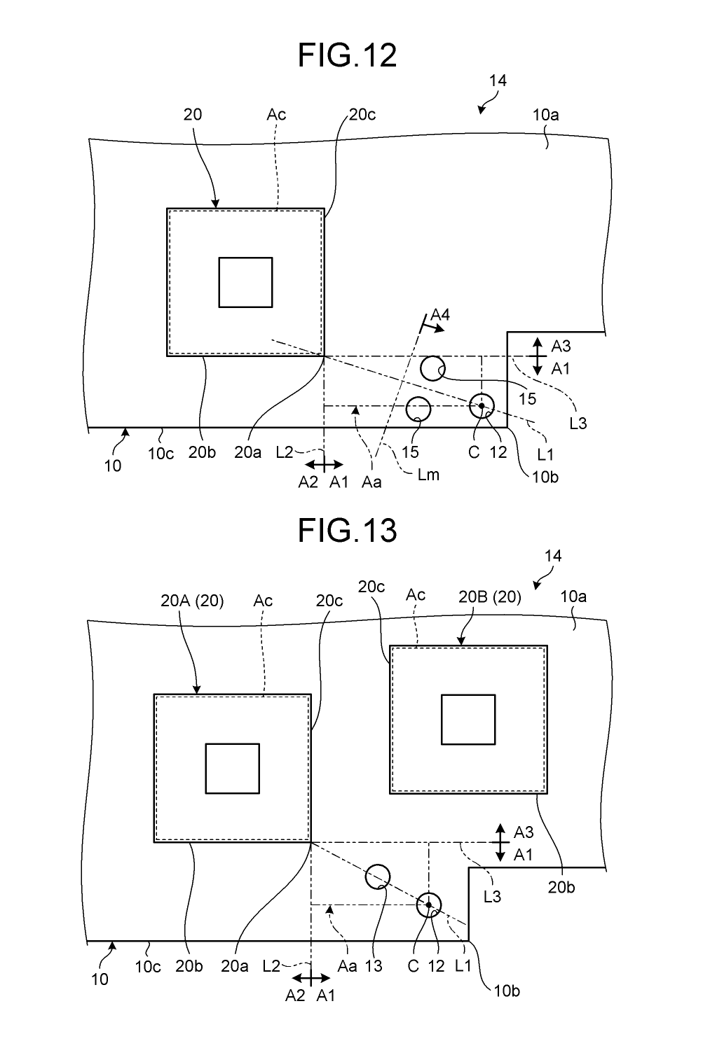

In this modification, as illustrated in FIG. 12, the substrate 10 has a plurality of (in the modification, two as an example) openings 15 (third openings) that are not overlapped with the straight line L1 as an example. The openings 15 are through-holes provided on the substrate 10. In the modification, the openings 15 are circular through-holes when viewed from the above, as an example. The openings 15 are provided in which at least a part of them are overlapped with or make contact with the region A1 or Aa (in the modification, are overlapped therewith, as an example). Furthermore, the openings 15 are located in the region A4. That is to say, the openings 15 are located at positions closer to the center C of the opening 12 rather than to the corner 20a. Studies by the inventors have revealed that the openings 15, when provided, tends to reduce stress in the bonding region Ac in comparison with a case without the openings 15. That is to say, the modification tends to further suppress increases in stress in the bonding region Ac due to the external force input from the coupling tool 11 and in energy to be transmitted as a stress wave, as an example.

Sixth Modification

With the arrangement of a plurality of parts 20 (20A and 20B) and the opening 12 according to this modification as illustrated in FIG. 13, the external force input from the opening 12 (coupling tool 11) has a larger influence on the part 20A than on the part 20B. This is because the opening 12 is arranged so as to be opposed to the corner 20a of the part 20A and to the side 20b of the part 20B. In the modification, as illustrated in FIG. 13, the opening 13 is provided on the straight line L1 connecting the center C of the opening 12 and the corner 20a of the part 20A in the regions A1 and Aa viewed from the thickness direction of the substrate 10 as in the first modification, as an example. Thus, according to the modification, the opening 13 tends to suppress an increase in stress in the region corresponding to the corner 20a of the bonding region Ac corresponding to the part 20A.

Seventh Modification

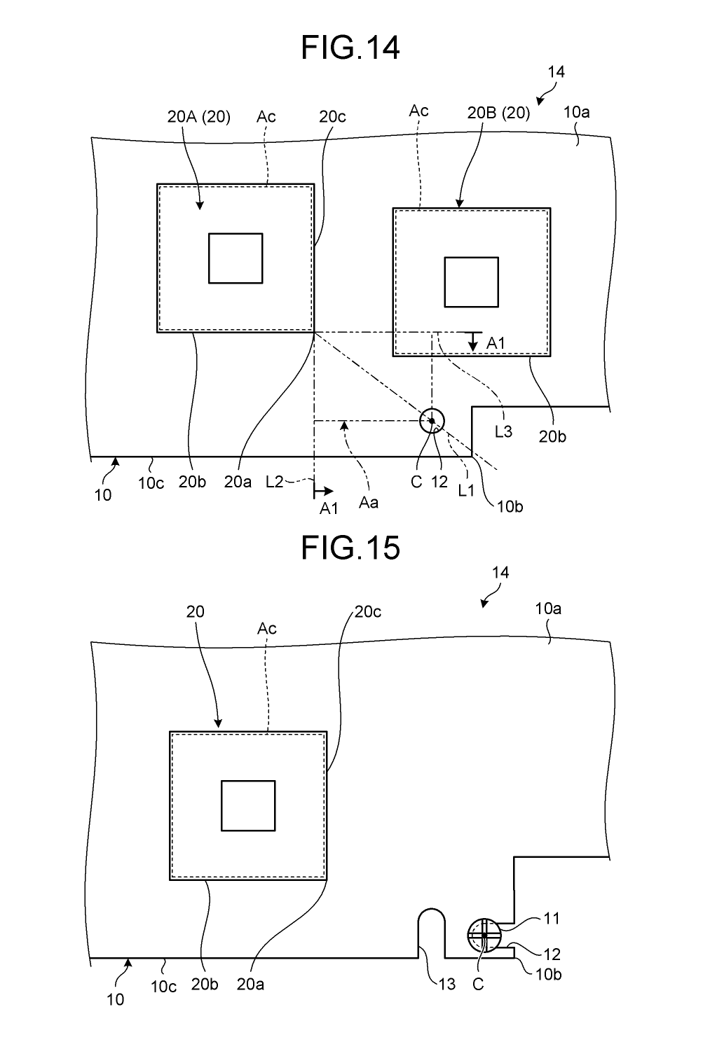

With the arrangement of the parts 20 (20A and 20B) and the opening 12 according to this modification as illustrated in FIG. 14, no opening 13 is provided. That is to say, in the modification, the part 20B is located in the region Aa corresponding to the corner 20a of the part 20A. Furthermore, the opening 12 is located so as to be opposed to the side 20b of the part 20B. Accordingly, with the configuration as in the modification where the openings 13 and 15 in the above-mentioned embodiments and modifications are not provided, stress on the bonding region Ac can still be within an allowable range in some cases.

Eighth Modification

A configuration according to this modification as illustrated in FIG. 15 is the same as the configuration in the above-mentioned embodiments except that, in the modification, the opening 12 is a cutout provided on the end 10c of the substrate 10, as an example. In the modification, the same or similar results (effects) as those obtained in the above-mentioned embodiments can be obtained.

The embodiments of the invention have been described but these embodiments are merely examples and do not intend to limit the range of the invention. These embodiments can be executed in other various modes and various omissions, replacements, combinations, and changes can be made in a range without departing from the scope of the invention. These embodiments and modifications thereof are encompassed in the range and scope of the invention and are encompassed in the invention, which is described in the scope of the invention, and equivalents thereof. The invention is not limited to the above-mentioned embodiments and various modifications can be made. In addition, the specifications (configuration, type, direction, shape, size, length, width, thickness, height, number, arrangement, position, material, and the like) of individual components can be changed to be appropriate for practical use. For example, the corners of the part may be chamfered.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a housing;
a display device in the housing;
a substrate in the housing and comprising a first opening; and
a part on a surface of the substrate and comprising a square outer shape when viewed from a direction normal to the substrate, wherein
the substrate comprises a second opening in a first region, the first region formed by a first line extending from a first side of the part and a second line extending from a second side of the part, the first line crossing the second line at a corner of the part, and at a side opposite to the part when viewed from the direction normal to the substrate, wherein the second opening is on a line connecting the corner and a center of the first opening.

2. The television receiver of claim 1, wherein at least a part of the second opening is located in a rectangular second region, the rectangular second region formed with the line connecting the corner and the center of the first opening as a diagonal line.

3. The television receiver of claim 2, wherein the second opening is located closer to the first opening than to the corner of the part.

4. The television receiver of claim 2, wherein the substrate comprises a third opening in the second region.

5. The television receiver of claim 1, wherein the second opening is a cutout on an end of the substrate.

6. The television receiver of claim 5, wherein the second opening is on an end of the substrate along a lengthwise direction of the substrate.

7. The television receiver of claim 1, wherein the second opening is a through-hole on the substrate.

8. An electronic apparatus comprising:
a housing;
a substrate in the housing and comprising a first opening; and
a part on a surface of the substrate and comprising a square outer shape when viewed from a direction normal to the substrate, wherein
the substrate comprises a second opening in a first region, the first region formed by a first line extending from a first side of the part and a second line extending from a second side of the part, the first line crossing the second line at a corner of the part, and at a side opposite to the part when viewed from the direction normal to the substrate, wherein the second opening is on a line connecting the corner and a center of the first opening.

9. A substrate assembly comprising:
a substrate comprising a first opening; and
a part on a surface of the substrate and comprising a square outer shape when viewed from a direction normal to the substrate, wherein
the substrate comprises a second opening in a first region, the first region formed by a first line extending from a first side of the part and a second line extending from a second side of the part, the first line crossing the second line at a corner of the part, and at a side opposite to the part when viewed from the direction normal to the substrate, wherein the second opening is on a line connecting the corner and a center of the first opening.
